(19) United States
(12) Patent Application Publication
(10) Pub. No.: US 2018/0223129 A1
(43) Pub. Date: Aug. 9, 2018

(54) POLISHING COMPOSITION AND POLISHING METHOD

(71) Applicant: SHIN-ETSU CHEMICAL CO., LTD., Tokyo (JP)

(72) Inventor: Yoshihiro NOJIMA, Annaka (JP)

(73) Assignee: SHIN-ETSU CHEMICAL CO., LTD., Tokyo (JP)

(21) Appl. No.: 15/506,644

(22) PCT Filed: Jul. 2, 2015
(86) PCT No.: PCT/JP2015/003328

§ 371 Date: Feb. 24, 2017

(30) Foreign Application Priority Data
Sep. 12, 2014 (JP) 2014-186114

(51) Int. Cl. C09G 1/02; H01L 21/321; B24B 37/04

(52) U.S. Cl. CPC C09G 1/02; B24B 37/044; H01L 21/3212

(57) ABSTRACT

A polishing composition includes: metal oxide particles as abrasive grains, wherein the full width at half maximum of a peak portion having the maximum diffracted intensity in an X-ray powder diffraction pattern of the metal oxide particles is less than 1°; and two or more varieties of water-soluble polymers having different weight-average molecular weights as a selectivity control agent, wherein the water-soluble polymers differ in weight-average molecular weight by 10 times or more. A polishing composition and a method for polishing a semiconductor substrate using thereof can suppress occurrence of defects due to polishing such as a scratch, dishing, and erosion while keeping the high polishing rate, and can optionally control the selectivity, which is a ratio of polishing speed of a metal layer and that of an insulator layer.

### TECHNICAL FIELD

The present invention relates to a polishing composition and a polishing method.

### BACKGROUND ART

As the improvement on production technology for semiconductor integrated circuits, high integration and high-speed performance of semiconductor devices are demanded. Accordingly, stricter flatness is demanded for the surfaces of semiconductor substrates in production processes of fine circuits in semiconductor devices, and polishing such as Chemical Mechanical Polishing (CMP) has been an essential technology for production processes of semiconductor devices thereby.

In wiring processes, each of which is one of a process for manufacturing a semiconductor device, grooves formed on an insulator layer are filled with metal material such as tungsten, copper, and aluminum to deposit a metal layer onto the groove portions. In order to remove unnecessary portions of this metal layer, CMP is utilized. In semiconductor memory devices, it has been investigated to use metal material also for device portions such as gate electrodes in order to further improve the performances. CMP is also used in this process (see Patent Documents 1, 2, 3, and 4).

CMP is based on relative movement of a semiconductor substrate and a polishing pad while the semiconductor substrate is held and pressed against the polishing pad attached onto a turn table. In this time, a polishing composition containing abrasive grains and reagents is supplied onto the polishing pad. This brings a chemical reaction with the reagent and a mechanical polishing effect of the abrasive grains, and makes it possible to grind unevenness on the surface of the semiconductor substrate to flatten the surface.

In CMP process, important characteristics are polishing speed (polishing rate) and defects due to polishing such as a scratch, dishing, which is a concave on a buried pattern portion, and erosion, in which film thicknesses of the insulator portion other than the wiring region is decreased. Since polishing speed relates to productivity in a semiconductor producing process, and productivity influences to the cost of the semiconductor device, higher polishing speed is required. On the other hand, since the foregoing defects cause variation in properties of the semiconductor devices and influence to the yield and reliability of a semiconductor device, the important problem is how to suppress defect occurrence in a CMP process. Accordingly, a polishing process on a higher level comes to be demanded in accordance with miniaturization of semiconductor devices.

Patent Documents 5 and 6 describes polishing compositions that can control the selectivity, which is defined as a ratio of polishing speed of a metal layer and that of an insulator layer for suppressing the erosion. Higher selectivity, however, tends to polish the metal layer excessively relative to the insulator layer in accordance with the polishing proceeds to cause dishing and a scratch on the insulator layer. On the other hand, when the selectivity is lowered, the occurrence of dishing and a scratch can be suppressed, but the difference of the polishing speed of the metal layer and that of the insulator layer becomes small, which promotes polishing of the insulator layer to tend to cause erosion.

### CITATION LIST

### Patent Literature

Patent Document 1: Japanese Examined Patent Application publication (Koukoku) No. H7-77218

Patent Document 2: Japanese Examined Patent Application publication (Koukoku) No. H8-21557

Patent Document 3: Japanese Unexamined Patent Application publication (Translation of PCT Application) No. 2008-515190

Patent Document 4: Japanese Unexamined Patent Application publication (Kokai) No. 2013-145800

Patent Document 5: Japanese Patent No. 2819196

Patent Document 6: Japanese Unexamined Patent Application publication (Kokai) No. 2006-228823

### SUMMARY OF INVENTION

### Technical Problem

The present invention was accomplished in view of the above-described problems. It is an object of the present invention to provide a polishing composition and a method for polishing a semiconductor substrate using thereof that can suppress occurrence of defects due to polishing such as a scratch, dishing, and erosion while keeping the high polishing rate, and can optionally control the selectivity, which is a ratio of polishing speed of a metal layer and that of an insulator layer.

### Solution to Problem

To achieve the foregoing object, the present invention provides a polishing composition, comprising: metal oxide particles as abrasive grains, wherein the full width at half maximum of a peak portion having the maximum diffracted intensity in an X-ray powder diffraction pattern of the metal oxide particles is less than 1°; and two or more varieties of water-soluble polymers having different weight-average molecular weights as a selectivity control agent, wherein the water-soluble polymers differ in weight-average molecular weight by 10 times or more.

By comprising highly crystalline metal oxide particles having a full width at half maximum of less than 1° and two or more varieties of water-soluble polymers which differ in weight-average molecular weights by 10 times or more, the polishing composition can keep the polishing speed high; can suppress occurrence of defects such as a scratch, dishing, and erosion; and can easily control the selectivity to an optional value.

The metal oxide particles can contain any one variety selected from the group consisting of titanium oxide, zirconium oxide, cerium oxide, aluminum oxide, manganese oxide, mixtures of two or more of these metal oxides, and complex oxides containing at least one of these metal oxides.

As metal oxide particles used in the present invention, metal oxide particles containing these are suitable.

The water-soluble polymers can comprise at least one variety selected from the group consisting of policarboxylic acid and salts thereof, poly(styrenesulfonic acid) and salts thereof, polyacrylic acid and salts thereof, polyvinylpyrrolidone, anion modified polyvinyl alcohol, polyacrylamide, and polyether.

As water-soluble polymers used in the present invention, water-soluble polymers containing these are suitable.

It is preferable that the inventive polishing composition further comprise an oxidizing agent.

By containing an oxidizing agent, it is possible to oxidize the surface of a semiconductor substrate, and to promote polishing effectively thereby.

As the oxidizing agent, it is preferable to comprise at least one variety selected from the group consisting of peroxides and iron(III) salts.

It is preferred that the peroxide comprise at least one variety selected from the group consisting of persulfuric acid, periodic acid, perchloric acid, salts thereof, and hydrogen peroxide.

It is preferred that the iron(III) salt comprise at least one variety selected from the group consisting of iron(III) sulfate, iron(III) nitrate, iron(ITT) chloride, iron(III) oxalate, potassium tris(oxalate)ferrate(III), ammonium hexacyanoferrate(III), potassium hexacyanoferrate(III), iron(III) citrate, and ammonium iron(III) citrate.

By containing these as an oxidizing agent, it is possible to oxidize the surface of a semiconductor substrate suitably, and to promote polishing more effectively thereby.

The present invention also provides a polishing method comprising polishing of a semiconductor substrate by using the foregoing polishing composition to achieve the foregoing object.

The use of the foregoing polishing composition makes it hard to generate a scratch, dishing, and erosion while keeping the polishing speed high. Moreover, it becomes easy to control the selectivity.

It is preferred that the semiconductor substrate contain a metal layer.

The present invention is suitable for polishing a semiconductor substrate containing a metal layer.

The metal layer preferably comprises tungsten or tungsten alloy.

The present invention is particularly suitable for polishing a semiconductor substrate containing tungsten or tungsten alloy as the metal layer.

### Advantageous Effects of Invention

The inventive polishing composition and the polishing method using thereof can easily control the selectivity to an optional value while keeping the high polishing rate and suppressing occurrence of defects due to polishing.

### BRIEF DESCRIPTION OF DRAWINGS

FIG. 1 is a schematic diagram to show an example of a single-side polishing apparatus that can be used for a polishing method of the present invention.

### DESCRIPTION OF EMBODIMENTS

Hereinafter, the embodiments of the present invention will be described, but the present invention is not limited thereto.

First, the inventive polishing composition will be described.

The inventive polishing composition contains abrasive grains of metal oxide particles of which the full width at half maximum of a peak portion having the maximum diffracted intensity in the X-ray powder diffraction pattern is less than 1°, and contains two or more varieties of water-soluble polymers having different weight-average molecular weights as a selectivity control agent, in which the water-soluble polymers differ in weight-average molecular weight by 10 times or more. Incidentally, the selectivity control agent refers to a material to control the selectivity, which is a ratio of the polishing speeds, such as a material to control the selectivity of the polishing speed of a metal layer and that of an insulator layer to an optional value in polishing of a semiconductor wafer.

By using highly crystalline metal oxide particles having a full width at half maximum of less than 1° as in the present invention, the polishing speed and the properties of defects such as a scratch and dishing are improved compared to the case using metal oxide powders having s full width at half maximum of 1° or more. Although the specific mechanism is unknown at this time, it is conceivable that this is probably due to the effective hardness of the metal oxide particles or a chemical interaction between the surface of the metal oxide particles and the surface of an object to be polished.

This full width at half maximum of the metal oxide particles contained in the inventive polishing composition can be determined on the basis of an X-ray pattern obtained by a θ-2θ method using Cu—Kα ray, which has a wavelength of 1.5418 (Å), as an X-ray source, for example. The full width at half maximum means a peak width of the peak having the maximum intensity at a position in which the intensity is half of the peak intensity with the background being excluded therefrom.

In the present invention, the crystal structure of the metal oxide particles is not particularly limited. It can have a single crystal phase or plural of crystal phases so long as the full width at half maximum is less than 1°. The metal oxide may be a complex oxide, and can be appropriately selected in accordance with an object to be polished or the purpose.

As the metal oxide, any one of metal oxide selected from the group consisting of titanium oxide, zirconium oxide, cerium oxide, aluminum oxide, and manganese oxide; or a mixture of two or more of these metal oxides is suitable. The complex oxide is suitably a complex oxide which contains at least one metal oxide selected from the group consisting of titanium oxide, zirconium oxide, cerium oxide, aluminum oxide, and manganese oxide. Illustrative examples of the complex oxide include zirconia/ceria complex oxide, alumina/ceria complex oxide, zirconia/yttria complex oxide, and iron/manganese complex oxide, but is not limited thereto.

The metal oxide particles preferably have an average primary particle size of 10 nm or more and 400 nm or less. When the average primary particle size of the metal oxide particles is 10 nm or more, sufficient polishing speed can be obtained. When it is 400 nm or less, occurrence of scratches can be decreased. The particle size distribution of the metal oxide particles is not particularly limited so long as the particle size is in this range, and can be altered appropriately in accordance with the purpose.

The average primary particle size of the metal oxide particles is preferably calculated from an average value of maximum of unidirectional diameters, i.e. Feret diameters, of 100 or more of the particles subsequent to measure the particle images obtained by Transmission Electron Microscope (TEM) or Scanning Electron Microscope (SEM).

The content of the metal oxide particles in the polishing composition is preferably 0.1% by mass or more and 10% by mass or less, particularly preferably 0.3% by mass or more and 3% by mass or less. When the content of the metal oxide particles is 0.1% by mass or more, sufficient polishing speed can be obtained. When the content of the metal oxide particles is 10% by mass or less, occurrence of defects such as a scratch can be suppressed.

The method for producing metal oxide particles is not particularly limited, and can be appropriately selected in accordance with the purpose. Illustrative examples thereof include a method of pyrolyzing a precursor of the metal oxide formed by precipitation method and so on (see Japanese Unexamined Patent Application publication No. 2006-32966), a sol-gel method by hydrolysis of metal alkoxide (see Japanese Unexamined Patent Application publication No. 2013-18690), a spray decomposition method in which metal chloride gas or metal salt is sprayed and decomposed by heat or plasma (see Japanese Unexamined Patent Application publication No. H6-40726), a hydrothermal synthesis method in which metal salt solution is reacted in a supercritical state water (see Japanese Unexamined Patent Application publication No. 2008-137884), and a laser ablation method in which target material is irradiated with laser to be evaporated instantaneously and reaggregated (see WO 2012/114923). As a method for producing a high-crystalline metal oxide particle, the following are known: a method to react oxide of titanium or zinc with Ba and so on in an aqueous alkaline metal hydroxide solution with 10 molar concentration or more (see Japanese Unexamined Patent Application publication No. 2007-31176) or a heat treatment method of metal oxide sol and metal salt by increasing the temperature in a flow reaction apparatus (see Japanese Unexamined Patent Application publication No. 2012-153588). By selecting these production method or producing conditions appropriately in accordance with the purpose, the crystallinity of metal oxide to be produced can be controlled.

As the water-soluble polymers contained in the inventive polishing composition, at least one variety selected from the group consisting of policarboxylic acid and salts thereof, poly(styrenesulfonic acid) and salts thereof, polyacrylic acid and salts thereof, polyvinylpyrrolidone, anion modified polyvinyl alcohol, polyacrylamide, and polyether is suitably used. The anion modified polyvinyl alcohol preferably has a modifying group such as a carboxy group, a sulfone acid group, and a silanol group. The number of the modifying group in the anion modified polyvinyl alcohol can be adjusted appropriately in accordance with the purpose. The polymerization degree or molecular weight of the water-soluble polymer is not particularly limited, and can be selected appropriately in accordance with the variety and particle size of the metal oxide particles to be used as well as an object to be polished. The water-soluble polymers contained in the polishing composition can suppress erosion by the interaction between the surface to be polished and the surface of the metal oxide particles, which are abrasive grains.

The polymerization degree of the water-soluble polymer changes an influence of the interaction between the surface of the metal oxide abrasive grains and the surface of an object to be polished. In general, when the polymerization degree is low and the weight-average molecular weight is low, the interaction is weak and an influence to lower the polishing speed is small, but the effect to suppress defects such as erosion is small. On the other hand, when the polymerization degree is high and the weight-average molecular weight is high, the interaction becomes strong and the influence to lower the polishing speed is large, but the effect to suppress defects such as erosion becomes strong. By combining and using these effects, that is, by combining two or more varieties of water-soluble polymers having different weight-average molecular weights and making the water-soluble polymers to be combined differ in weight-average molecular weight by 10 times or more, it becomes possible to control the erosion amount etc. while suppressing the lowering of the polishing speed. It is to be noted that the water-soluble polymers having different weight-average molecular weights may be the same or different, and not particularly limited.

The inventive polishing composition can optionally control the selectivity in polishing by appropriately adjusting the blending ratio of the water-soluble polymers having different weight-average molecular weights and each weight-average molecular weight in accordance with material of an object to be polished, together with pattern width and pattern density formed on the object to be polished.

As described above, the present invention acts as a polishing composition that can keep the polishing rate high; can suppress occurrence of a scratch, dishing, and erosion; and can easily control the selectivity by combining and using the abrasive grains composed of highly crystalline metal oxide particles of which the full width at half maximum of a peak portion having the maximum diffracted intensity in the X-ray powder diffraction pattern is less than 1°, together with the selectivity control agent composed of two or more varieties of water-soluble polymers of which the weight-average molecular weights are in a ratio of 10 or more to one from each other.

The inventive polishing composition may further comprise an oxidizing agent. This oxidizing agent is not particularly limited, but it is preferable to contain at least one of an iron(III) salt and an organic or inorganic compound composed of peroxide. As the peroxide, though it is not particularly limited, it is preferable to contain at least one variety selected from the group consisting of persulfuric acid, periodic acid, perchloric acid, salts thereof, and hydrogen peroxide. As the compound composed of an iron(III) salt, though it is not particularly limited, it is preferable to contain at least one variety selected from the group consisting of iron(III) sulfate, iron(III) nitrate, iron(III) chloride, iron(III) oxalate, potassium tris(oxalate)ferrate(III), ammonium hexacyanoferrate(III), potassium hexacyanoferrate(III), iron(III) citrate, and ammonium iron(III) citrate.

When the inventive polishing composition contains such an oxidizing agent, it is possible to oxidize the surface of a semiconductor substrate, and to promote polishing effectively thereby.

To the inventive polishing composition, it is possible to add an anionic polymer, a cationic polymer, and a nonionic polymer as a dispersant. The variety, structure and molecular weight of these polymers are not particularly limited, and can be appropriately selected in accordance with the purpose. Illustrative examples of the usable polymer include policarboxylic acid and poly(styrenesulfonic acid) as the anionic polymer, alkyltrimethylammonium salts and alkylamide amine salts as the cationic polymer, and sorbitan carboxylate as the nonionic polymer.

In the inventive polishing composition, the pH is not particularly limited, and can be appropriately selected in accordance with an object to be polished and the purpose. For example, when polishing the surface containing tungsten, the pH is preferably 1 or more and 6 or less. Illustrative examples of a means to adjust the pH of the polishing composition include use of an inorganic acid such as nitric acid, hydrochloric acid, and sulfuric acid; an organic acid such as acetic acid, oxalic acid, and succinic acid; an inorganic base such as potassium hydroxide and ammonia; and an organic base such as Tetramethylammonium hydroxide (TMAH).

Subsequently, the polishing method by using the inventive polishing composition will be described. The following describes an example of single-side polishing of a semiconductor substrate, but the present invention is not limited thereto naturally. It is possible to use the inventive polishing composition to double-side polishing, etc.

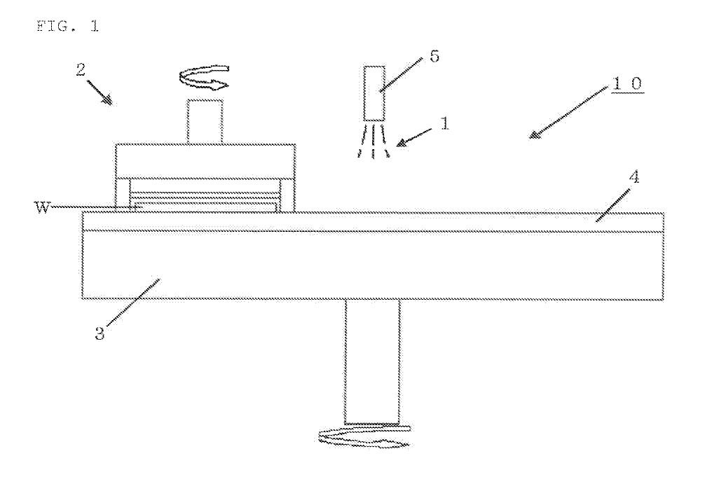

The single-side polishing apparatus can be a single-side polishing apparatus 10 composed of a turn table 3 attached with a polishing pad 4, a polishing composition supply mechanism 5, a polishing head 2, and so on as described in FIG. 1, for example.

In such a polishing apparatus 10, a semiconductor substrate W is held by the polishing head 2, while supplying the inventive polishing composition 1 onto the polishing pad 4 through the polishing composition supply mechanism 5, each of the turn table 3 and the polishing head 2 is rotated, and the surface of the semiconductor substrate W is brought into sliding contact with the polishing pad 4 to perform polishing.

In this case, the semiconductor substrate W can contain a metal layer, and the metal layer can comprise tungsten or tungsten alloy.

The inventive polishing method is suitable for polishing a surface containing a metal layer as an object to be polished, and is suitably used for polishing a metal layer composed of tungsten or tungsten alloy.

The polishing method using the inventive polishing composition can keep the polishing rate high, and can suppress occurrence of a scratch, dishing, and erosion. It is also possible to optionally control the selectivity in polishing by appropriately adjusting the blending ratio of the water-soluble polymers having different weight-average molecular weights and each weight-average molecular weight in the polishing composition to be used in accordance with material of an object to be polished as well as pattern width and pattern density formed on the object to be polished.

### EXAMPLE

Hereinafter, the present invention will be more specifically described with reference to Examples and Comparative Examples, but the present invention is not limited thereto.

### Example 1

Semiconductor substrates were polished by using the inventive polishing compositions to evaluate the dishing amounts, the erosion amounts, the polishing speeds (polishing rates), the selectivity, and the existence and nonexistence of a scratch in the polished semiconductor substrates.

The polishing compositions used in Example 1 were produced as follows.

First, zirconium oxide having a crystal structure of a monoclinic form, an X-ray full width at half maximum of 0.4169°, and an average primary particle size of 35 nm was dispersed into pure water so as to have the content of 1.0% by mass. Then, polyacrylic acid with a weight-average molecular weight of 5,000 and polyacrylic acid with a weight-average molecular weight of 100,000 were added as the water-soluble polymers in each concentration shown in Conditions 1-a to 1-e in Table 1 given below. As described above, in Example 1, five varieties of aqueous solutions were prepared by adding the same kind of water-soluble polymers having weight-average molecular weights which differ by 20 times. Then, 1.5% by mass of hydrogen peroxide and 0.1% by mass of iron(III) nitrate were added and mixed to these solutions. Subsequently, the pH of the solution was adjusted to 2.5 by nitric acid. As described above, five varieties of polishing compositions with different concentrations of the water-soluble polymers were produced.

It is to be noted that, the full width at half maximum of the zirconium oxide was measured with RINT2500 manufactured by Rigaku Corporation under the conditions of the receiving slit size of 0.3 mm, the tube voltage of 50 kV, the tube current of 60 mA, the scan speed of 3°/min, and the sampling width of 0.024°.

TABLE 1

| | | 1) polyacrylic | | | |
|---|---|---|---|---|---|
| | Zirconium | acid (molecular | | | |
| | oxide | weight: 5,000) | | | |
| | full width at | 2) polyacrylic | | | |
| Condi- | half maximum | acid (molecular | Hydrogen | Iron (III) | |
| tions | (°) = 0.4169 | weight: 100,000) | peroxide | nitrate | pH |
| 1-a | 1.0% by | 1) 0.10% by mass | 1.5% by | 0.1% by | 2.5 |
| | mass | 2) 0.01% by mass | mass | mass | |
| 1-b | 1.0% by | 1) 0.02% by mass | 1.5% by | 0.1% by | 2.5 |
| | mass | 2) 0.08% by mass | mass | mass | |
| 1-c | 1.0% by | 1) 0.05% by mass | 1.5% by | 0.1% by | 2.5 |
| | mass | 2) 0.05% by mass | mass | mass | |
| 1-d | 1.0% by | 1) 0.08% by mass | 1.5% by | 0.1% by | 2.5 |
| | mass | 2) 0.02% by mass | mass | mass | |
| 1-e | 1.0% by | 1) 0.01% by mass | 1.5% by | 0.1% by | 2.5 |
| | mass | 2) 0.10% by mass | mass | mass | |

In the evaluation of the polishing speed and the selectivity, the polishing speed in polishing of a tungsten film and the polishing speed in polishing of a silicon oxide film were measured, and the ratio of these polishing speeds was determined as selectivity.

In the polishing of a tungsten film, an object to be polished was a blanket substrate in which about 800 nm of a tungsten layer had been deposited through a titanium nitride layer with a thickness of about 10 nm onto a silicon substrate with a diameter of 12 inches (300 mm). The polishing was performed by using each of the five varieties of the polishing compositions, and each amount of change of the thicknesses of the tungsten film (film thicknesses) before and after the polishing was divided by time (min) to determine a polishing speed. The film thickness was determined by the following equation 1 on the basis of a seat resistivity measured with 4-point prove resistivity measuring instrument (RT-70V manufactured by NAPSON CORPORATION).

ρ=ρₛ×t (equation 1)

(wherein, ρ is a specific resistivity (constant), ρₛ is a seat resistivity, and t is a film thickness)

In the polishing of a silicon oxide film, an object to be polished was a blanket substrate in which about 1000 nm of a High Density Plasma (HDP) silicon oxide layer had been deposited onto a silicon substrate with a diameter of 12 inches (300 mm). The polishing was performed by using each of the five varieties of the polishing compositions, and each amount of change of the thicknesses of the silicon oxide film before and after the polishing was divided by time (min) to determine a polishing speed. The film thickness of the silicon oxide film was measured with an ellipsometer (SE800 manufactured by SENTECH instruments GmbH). On the basis of a ratio of the polishing speed of a tungsten film and the polishing speed of a silicon oxide film determined as described above, the selectivity (the polishing speed of a tungsten film/the polishing speed of a silicon oxide film) was calculated.

The evaluation of the dishing amount, the erosion amount and existence or nonexistence of a scratch were performed as follows.

The semiconductor substrate as an object to be polished was a patterned substrate in which tungsten with a thickness of about 600 nm was deposited through a titanium nitride layer with a thickness of about 1 nm onto linear grooves having a width of 100 nm and a depth of 200 nm with a spacing of 100 nm to fill the groove portions. The polishing was performed by using each of the five varieties of the polishing compositions. The patterned portions after the polishing were cut out, and each cross section was observed under an electron microscope to evaluate the difference between the non-pattern area without grooves and most concave portion in the portion filled with tungsten as a dishing amount. The erosion was evaluated similarly by cutting out the patterned portions and evaluating the decrease of the film thickness of the insulator layer before and after the polishing as an erosion amount.

The existence or nonexistence of a scratch was evaluated by observing arbitrary 10 points near the center of the substrate and arbitrary 10 points near the periphery of the substrate on the surface of the patterned substrate after the polishing under a laser microscope (1LM21 manufactured by Lasertec Corporation) to determine the existence or nonexistence of a scratch.

In Example 1, the polishing apparatus used was Poli-762 (manufactured by G&P Technology, Inc.), and the polishing pad used was IC1000 (manufactured by Nitta Haas Incorporated). The single-side polishing was performed under the polishing conditions such that the loading applied to a substrate to be polished was 193 g/cm², the rotational speed of the turn table was 70 rpm, the rotational speed of the polishing head was 70 rpm, and the amount of supplied slurry (polishing composition) was 100 mL/min.

The dishing amounts, the erosion amounts, the polishing speeds, the selectivity, and the existence and nonexistence of a scratch in Example 1, Examples 2 to 5 given later, and Comparative Examples 1 to 4 given later were shown in Tables 10 and 11.

As shown in Table 10, in Example 1, the dishing amounts could be suppressed equivalently or smaller than in Comparative Examples shown in Table 11, and the erosion amounts could be suppressed smaller than in Comparative Examples without generating a scratch. The polishing speeds were substantially larger than in Comparative Examples. The selectivity was changed in accordance with changes of the blending ratio of the water-soluble polymers (see the concentration of each water-soluble polymer in Table 1), which confirmed that the selectivity can be easily controlled to an optional ratio by adjusting the addition amount of each water-soluble polymer as in this Example 1, for example.

### Example 2

Each semiconductor substrate was polished under the same condition as in Example 1 except for changing the varieties of the water-soluble polymers to be added to the polishing composition and changing the weight-average molecular weights to differ by 14 times, whereby the dishing amount, the erosion amount, the polishing speed, the selectivity, and existence or nonexistence of a scratch were evaluated by the same method as in Example 1.

In Example 2, polyacrylic acid with a weight-average molecular weight of 5,000 and polyacrylic acid with a weight-average molecular weight of 70,000 were added as the water-soluble polymers in each concentration shown in Conditions 2-a to 2-e in Table 2 given below.

TABLE 2

| | | 1) polyacrylic | | | |
|---|---|---|---|---|---|
| | | acid (molecular | | | |
| | Zirconium | weight: 5,000) | | | |
| | oxide | 2) poly(styrene- | | | |
| | full width at | sulfonic acid) | | | |
| Condi- | half maximum | (molecular | Hydrogen | Iron (III) | |
| tions | (°) = 0.4169 | weight: 70,000) | peroxide | nitrate | pH |
| 2-a | 1.0% by | 1) 0.10% by mass | 1.5% by | 0.1% by | 2.5 |
| | mass | 2) 0.01% by mass | mass | mass | |
| 2-b | 1.0% by | 1) 0.02% by mass | 1.5% by | 0.1% by | 2.5 |
| | mass | 2) 0.08% by mass | mass | mass | |
| 2-c | 1.0% by | 1) 0.05% by mass | 1.5% by | 0.1% by | 2.5 |
| | mass | 2) 0.05% by mass | mass | mass | |
| 2-d | 1.0% by | 1) 0.08% by mass | 1.5% by | 0.1% by | 2.5 |
| | mass | 2) 0.02% by mass | mass | mass | |
| 2-e | 1.0% by | 1) 0.01% by mass | 1.5% by | 0.1% by | 2.5 |
| | mass | 2) 0.10% by mass | mass | mass | |

As shown in Table 10, in Example 2, the dishing amounts could be suppressed equivalently or smaller than in Comparative Examples shown in Table 11, and the erosion amounts could be suppressed smaller than in Comparative Examples without generating a scratch. The polishing speeds were substantially larger than in Comparative Examples. The selectivity was changed in accordance with changes of the blending ratio of the water-soluble polymers (see the concentration of each water-soluble polymer in Table 2), which confirmed that the selectivity can be easily controlled to an optional ratio.

### Example 3

Each semiconductor substrate was polished under the same condition as in Example 2 except for changing the metal oxide particles to be added to the polishing composition to the ones having a full width at half maximum of 0.9056°, whereby the dishing amount, the erosion amount, the polishing speed, the selectivity, and existence or nonexistence of a scratch were evaluated by the same method as in Example 2.

In Example 3, zirconium oxide having a crystal structure of a monoclinic form, an X-ray full width at half maximum of 0.9056°, and an average primary particle size of 40 nm was used as the metal oxide particles. As the water-soluble polymers, polyacrylic acid with a weight-average molecular weight of 5,000 and poly(styrenesulfonic acid) with a weight-average molecular weight of 70,000 were added in each concentration shown in Conditions 3-a to 3-e in Table 3 given below.

TABLE 3

| | | 1) polyacrylic | | | |
|---|---|---|---|---|---|
| | | acid (molecular | | | |
| | Zirconium | weight: 5,000) | | | |
| | oxide | 2) poly(styrene- | | | |
| | full width at | sulfonic acid) | | | |
| Condi- | half maximum | (molecular | Hydrogen | Iron (III) | |
| tions | (°) = 0.9056 | weight: 70,000) | peroxide | nitrate | pH |
| 3-a | 1.0% by | 1) 0.10% by mass | 1.5% by | 0.1% by | 2.5 |
| | mass | 2) 0.01% by mass | mass | mass | |
| 3-b | 1.0% by | 1) 0.02% by mass | 1.5% by | 0.1% by | 2.5 |
| | mass | 2) 0.08% by mass | mass | mass | |
| 3-c | 1.0% by | 1) 0.05% by mass | 1.5% by | 0.1% by | 2.5 |
| | mass | 2) 0.05% by mass | mass | mass | |
| 3-d | 1.0% by | 1) 0.08% by mass | 1.5% by | 0.1% by | 2.5 |
| | mass | 2) 0.02% by mass | mass | mass | |
| 3-e | 1.0% by | 1) 0.01% by mass | 1.5% by | 0.1% by | 2.5 |
| | mass | 2) 0.10% by mass | mass | mass | |

As shown in Table 10, the dishing amounts and the erosion amounts could be suppressed equivalently or smaller than in Comparative Examples without generating a scratch. The polishing speeds were greatly larger than in Comparative Examples given later. The selectivity was changed in accordance with changes of the blending ratio of the water-soluble polymers (see the concentration of each water-soluble polymer in Table 3), which revealed that the selectivity can be easily controlled to an optional ratio.

### Example 4

Each semiconductor substrate was polished under the same condition as in Example 1 except for using three varieties of water-soluble polymers to be added to the polishing composition, whereby the dishing amount, the erosion amount, the polishing speed, the selectivity, and existence or nonexistence of a scratch were evaluated by the same method as in Example 1.

In Example 4, polyacrylic acid with a weight-average molecular weight of 5,000, poly(styrenesulfonic acid) with a weight-average molecular weight of 70,000, and polyacrylamide with a weight-average molecular weight of 1,000,000 were added as the water-soluble polymers in each concentration shown in Conditions 4-a to 4-e in Table 4 given below.

TABLE 4

| | | 1) polyacrylic | | | |
|---|---|---|---|---|---|
| | | acid (molecular | | | |
| | | weight: 5,000) | | | |
| | | 2) poly(styrene- | | | |
| | | sulfonic acid) | | | |
| | Zirconium | molecular | | | |
| | oxide | weight: 70,000) | | | |
| | full width at | 3) polyacrylamide | | | |
| Condi- | half maximum | molecular weight: | Hydrogen | Iron (III) | |
| tions | (°) = 0.4169 | 1,000,000) | peroxide | nitrate | pH |
| 4-a | 1.0% by | 1) 0.01% by mass | 1.5% by | 0.1% by | 2.5 |
| | mass | 2) 0.01% by mass | mass | mass | |
| | | 3) 0.1% by mass | | | |
| 4-b | 1.0% by | 1) 0.05% by mass | 1.5% by | 0.1% by | 2.5 |
| | mass | 2) 0.05% by mass | mass | mass | |
| | | 3) 0.01% by mass | | | |
| 4-c | 1.0% by | 1) 0.05% by mass | 1.5% by | 0.1% by | 2.5 |
| | mass | 2) 0.01% by mass | mass | mass | |
| | | 3) 0.05% by mass | | | |
| 4-d | 1.0% by | 1) 0.01% by mass | 1.5% by | 0.1% by | 2.5 |
| | mass | 2) 0.05% by mass | mass | mass | |
| | | 3) 0.05% by mass | | | |
| 4-e | 1.0% by | 1) 0.03% by mass | 1.5% by | 0.1% by | 2.5 |
| | mass | 2) 0.03% by mass | mass | mass | |
| | | 3) 0.03% by mass | | | |

As shown in Table 10, the dishing amounts and the erosion amounts could be suppressed equivalently or smaller than in Comparative Examples given later without generating a scratch. The polishing speeds were substantially larger than in Comparative Examples given later. The selectivity was changed in accordance with changes of the blending ratio of the water-soluble polymers, which confirmed that the selectivity can be easily controlled to an optional ratio.

### Example 5

Each semiconductor substrate was polished under the same condition as in Example 1 except for changing the water-soluble polymers to be added to the polishing composition to have weight-average molecular weights which differed by 10 times, whereby the dishing amount, the erosion amount, the polishing speed, the selectivity, and existence or nonexistence of a scratch were evaluated by the same method as in Example 1.

In Example 5, polyacrylic acid with a weight-average molecular weight of 5000 and polyvinylpyrrolidone with a weight-average molecular weight of 50,000 were added as the water-soluble polymers in each concentration shown in Conditions 5-a to 5-e in Table 5 given below. As described above, the different varieties of water-soluble polymers which differed the weight-average molecular weights by 10 times were added in Example 5.

TABLE 5

| | | 1) polyacrylic | | | |
|---|---|---|---|---|---|
| | | acid (molecular | | | |
| | Zirconium | weight: 5,000) | | | |
| | oxide | 2) polyvinyl- | | | |
| | full width at | pyrrolidone | | | |
| Condi- | half maximum | (molecular | Hydrogen | Iron (III) | |
| tions | (°) = 0.4169 | weight: 50,000) | peroxide | nitrate | pH |
| 5-a | 1.0% by | 1) 0.10% by mass | 1.5% by | 0.1% by | 2.5 |
| | mass | 2) 0.01% by mass | mass | mass | |
| 5-b | 1.0% by | 1) 0.02% by mass | 1.5% by | 0.1% by | 2.5 |
| | mass | 2) 0.08% by mass | mass | mass | |
| 5-c | 1.0% by | 1) 0.05% by mass | 1.5% by | 0.1% by | 2.5 |
| | mass | 2) 0.05% by mass | mass | mass | |
| 5-d | 1.0% by | 1) 0.08% by mass | 1.5% by | 0.1% by | 2.5 |
| | mass | 2) 0.02% by mass | mass | mass | |
| 5-e | 1.0% by | 1) 0.01% by mass | 1.5% by | 0.1% by | 2.5 |
| | mass | 2) 0.10% by mass | mass | mass | |

As shown in Table 10, the dishing amounts and the erosion amounts could be suppressed equivalently or smaller than in Comparative Examples without generating a scratch. The polishing speeds were greatly larger than in Comparative Examples given later. The selectivity was changed in accordance with changes of the blending ratio of the water-soluble polymers on the whole (see the concentration of each water-soluble polymer in Table 5), which confirmed that the selectivity can be easily controlled to an optional ratio.

### Comparative Example 1

Each semiconductor substrate was polished under the same condition as in Example 1 except for changing the metal oxide particles to be added to the polishing composition to the ones having a full width at half maximum of 0.4917°, together with changing the water-soluble polymer to have weight-average molecular weights which differed by 2 times, whereby the dishing amount, the erosion amount, the polishing speed, the selectivity, and existence or nonexistence of a scratch were evaluated by the same method as in Example 1.

In Comparative Example 1, zirconium oxide having a crystal structure of a monoclinic form, an X-ray full width at half maximum of 0.4917°, and an average primary particle size of 61 nm was dispersed into pure water so as to have the content of 1.0% by mass at first. Then, polyacrylic acid with a weight-average molecular weight of 5000 and polyacrylic acid with a weight-average molecular weight of 10,000 were added as the water-soluble polymers in each concentration shown in Conditions 6-a to 6-e in Table 6 given below. As described above, the same kind of water-soluble polymers which differed the weight-average molecular weights by 2 times were added in Comparative Example 1. To each of these aqueous solutions, 1.5% by mass of hydrogen peroxide and 0.1% by mass of iron(III) nitrate were added and mixed. Subsequently, the pH of the solution was adjusted to 2.5 by nitric acid. As described above, five varieties of polishing compositions with different concentrations of the water-soluble polymers were produced.

TABLE 6

| | | 1) polyacrylic | | | |
|---|---|---|---|---|---|
| | Zirconium | acid (molecular | | | |
| | oxide | weight: 5,000) | | | |
| | full width at | 2) polyacrylic | | | |
| Condi- | half maximum | acid (molecular | Hydrogen | Iron (III) | |
| tions | (°) = 0.4917 | weight: 10,000) | peroxide | nitrate | pH |
| 6-a | 1.0% by | 1) 0.10% by mass | 1.5% by | 0.1% by | 2.5 |
| | mass | 2) 0.01% by mass | mass | mass | |
| 6-b | 1.0% by | 1) 0.02% by mass | 1.5% by | 0.1% by | 2.5 |
| | mass | 2) 0.08% by mass | mass | mass | |
| 6-c | 1.0% by | 1) 0.05% by mass | 1.5% by | 0.1% by | 2.5 |
| | mass | 2) 0.05% by mass | mass | mass | |
| 6-d | 1.0% by | 1) 0.08% by mass | 1.5% by | 0.1% by | 2.5 |
| | mass | 2) 0.02% by mass | mass | mass | |
| 6-e | 1.0% by | 1) 0.01% by mass | 1.5% by | 0.1% by | 2.5 |
| | mass | 2) 0.10% by mass | mass | mass | |

As a result, the dishing amounts were equivalent or increased compared to those in the foregoing Examples, and the erosion amounts were increased, as shown in Table 11. The polishing speeds, particularly the polishing speed of each tungsten film was lowered than in the foregoing Examples. The selectivity was varied irregularly unrelated to the blending ratio of the water-soluble polymers, which revealed that the selectivity cannot be controlled to an optional ratio when the weight-average molecular weights of the water-soluble polymers differ by less than 10 times.

### Comparative Example 2

Each semiconductor substrate was polished under the same condition as in Example 2 except for changing the metal oxide particles to be added to the polishing composition to the ones having a full width at half maximum of 1.8413°, whereby the dishing amount, the erosion amount, the polishing speed, the selectivity, and existence or nonexistence of a scratch were evaluated.

In Comparative Example 2, zirconium oxide having a crystal structure of a monoclinic form, an X-ray full width at half maximum of 1.8413°, and an average primary particle size of 45 nm was used as the metal oxide particles. As the water-soluble polymers, polyacrylic acid with a weight-average molecular weight of 5,000 and polyacrylic acid with a weight-average molecular weight of 70,000 were added in each concentration shown in Conditions 7-a to 7-e in Table 7 given below. As described above, the polishing composition in which the X-ray full width at half maximum of the metal oxide particles was 1° or more was used in Comparative Example 2.

TABLE 7

| | | 1) polyacrylic | | | |
|---|---|---|---|---|---|
| | | acid (molecular | | | |
| | Zirconium | weight: 5,000) | | | |
| | oxide | 2) poly(styrene- | | | |
| | full width at | sulfonic acid) | | | |
| Condi- | half maximum | (molecular | Hydrogen | Iron (III) | |
| tions | (°) = 1.8413 | weight: 70,000) | peroxide | nitrate | pH |
| 7-a | 1.0% by | 1) 0.10% by mass | 1.5% by | 0.1% by | 2.5 |
| | mass | 2) 0.01% by mass | mass | mass | |
| 7-b | 1.0% by | 1) 0.02% by mass | 1.5% by | 0.1% by | 2.5 |
| | mass | 2) 0.08% by mass | mass | mass | |
| 7-c | 1.0% by | 1) 0.05% by mass | 1.5% by | 0.1% by | 2.5 |
| | mass | 2) 0.05% by mass | mass | mass | |
| 7-d | 1.0% by | 1) 0.08% by mass | 1.5% by | 0.1% by | 2.5 |
| | mass | 2) 0.02% by mass | mass | mass | |
| 7-e | 1.0% by | 1) 0.01% by mass | 1.5% by | 0.1% by | 2.5 |
| | mass | 2) 0.10% by mass | mass | mass | |

As a result, the dishing amounts and the erosion amounts were substantially increased, and scratches were also occurred as shown in Table 11. As described above, it was confirmed that defects due to polishing increases substantially when the full width at half maximum of the metal oxide particles is 1° or more.

### Comparative Example 3

Each semiconductor substrate was polished under the same condition as in Example 2 except for changing the metal oxide particles to be added to the polishing composition to the ones having a full width at half maximum of 1.0957°, whereby the dishing amount, the erosion amount, the polishing speed, the selectivity, and existence or nonexistence of a scratch were evaluated by the same method as in Example 2.

As the metal oxide particles to be added, zirconium oxide having a crystal structure of a monoclinic form, an X-ray full width at half maximum of 1.0957°, and an average primary particle size of 61 nm was used. As the water-soluble polymers, polyacrylic acid with a weight-average molecular weight of 5,000 and poly(styrenesulfonic acid) with a weight-average molecular weight of 70,000 were added in each concentration shown in Conditions 8-a to 8-e in Table 8 given below.

TABLE 8

| | | 1) polyacrylic | | | |
|---|---|---|---|---|---|
| | | acid (molecular | | | |
| | Zirconium | weight: 5,000) | | | |
| | oxide | 2) poly(styrene- | | | |
| | full width at | sulfonic acid) | | | |
| Condi- | half maximum | (molecular | Hydrogen | Iron (III) | |
| tions | (°) = 1.0957 | weight: 70,000) | peroxide | nitrate | pH |
| 8-a | 1.0% by | 1) 0.10% by mass | 1.5% by | 0.1% by | 2.5 |
| | mass | 2) 0.01% by mass | mass | mass | |
| 8-b | 1.0% by | 1) 0.02% by mass | 1.5% by | 0.1% by | 2.5 |
| | mass | 2) 0.08% by mass | mass | mass | |
| 8-c | 1.0% by | 1) 0.05% by mass | 1.5% by | 0.1% by | 2.5 |
| | mass | 2) 0.05% by mass | mass | mass | |
| 8-d | 1.0% by | 1) 0.08% by mass | 1.5% by | 0.1% by | 2.5 |
| | mass | 2) 0.02% by mass | mass | mass | |
| 8-e | 1.0% by | 1) 0.01% by mass | 1.5% by | 0.1% by | 2.5 |
| | mass | 2) 0.10% by mass | mass | mass | |

As a result, the dishing amounts and the erosion amounts were increased, and scratches were also occurred as shown in Table 11. As described above, it was confirmed that defects due to polishing increases compared to those in Examples when the full width at half maximum of the metal oxide particles is 1° or more.

### Comparative Example 4

Each semiconductor substrate was polished under the same condition as in Example 1 except for changing the water-soluble polymer to have weight-average molecular weights which differed by 9 times in the polishing composition to be used, whereby the dishing amount, the erosion amount, the polishing speed, the selectivity, and existence or nonexistence of a scratch were evaluated by the same method as in Example 1.

In Comparative Example 4, polyacrylic acid with a weight-average molecular weight of 5000 and polyacrylic acid with a weight-average molecular weight of 45,000 were added as the water-soluble polymers in each concentration shown in Conditions 9-a to 9-e in Table 9 given below.

TABLE 9

| | | 1) polyacrylic | | | |
|---|---|---|---|---|---|
| | Zirconium | acid (molecular | | | |
| | oxide | weight: 5,000) | | | |
| | full width at | 2) polyacrylic | | | |
| Condi- | half maximum | acid (molecular | Hydrogen | Iron (III) | |
| tions | (°) = 0.4169 | weight: 45,000) | peroxide | nitrate | pH |
| 9-a | 1.0% by | 1) 0.10% by mass | 1.5% by | 0.1% by | 2.5 |
| | mass | 2) 0.01% by mass | mass | mass | |
| 9-b | 1.0% by | 1) 0.02% by mass | 1.5% by | 0.1% by | 2.5 |
| | mass | 2) 0.08% by mass | mass | mass | |
| 9-c | 1.0% by | 1) 0.05% by mass | 1.5% by | 0.1% by | 2.5 |
| | mass | 2) 0.05% by mass | mass | mass | |
| 9-d | 1.0% by | 1) 0.08% by mass | 1.5% by | 0.1% by | 2.5 |
| | mass | 2) 0.02% by mass | mass | mass | |
| 9-e | 1.0% by | 1) 0.01% by mass | 1.5% by | 0.1% by | 2.5 |
| | mass | 2) 0.10% by mass | mass | mass | |

As a result, the dishing amounts were equivalent or increased compared to those in the foregoing Examples, and the erosion amounts were increased, as shown in Table 11. As the polishing speeds, the polishing speed of each tungsten film was lowered than in the foregoing Examples. The selectivity was varied irregularly unrelated to the change of blending ratio of the water-soluble polymers, which confirmed that the selectivity cannot be controlled to an optional ratio as in Examples.

TABLE 10

| | | | | | Polishing | | |
|---|---|---|---|---|---|---|---|
| | | | | Polishing | speed of | | |
| | | | | speed of | silicon | | |
| | | Dishing | Erosion | tungsten | ox-ide | | |
| | Conditions | (Å) | (Å) | (Å/min) | (Å/min) | Selectivity | Scratch |
| Example 1 | 1-a | 71 | 16 | 3401 | 275 | 12 | None |
| | 1-b | 56 | 11 | 3374 | 112 | 30 | None |
| | 1-c | 60 | 8 | 3258 | 68 | 48 | None |
| | 1-d | 58 | 9 | 3354 | 60 | 56 | None |
| | 1-e | 64 | 10 | 3117 | 44 | 71 | None |
| Example 2 | 2-a | 68 | 11 | 3367 | 245 | 14 | None |
| | 2-b | 60 | 8 | 3120 | 147 | 21 | None |
| | 2-c | 51 | 13 | 3221 | 104 | 31 | None |
| | 2-d | 53 | 12 | 3057 | 62 | 49 | None |
| | 2-e | 66 | 9 | 3158 | 40 | 79 | None |
| Example 3 | 3-a | 74 | 18 | 3412 | 225 | 15 | None |
| | 3-b | 65 | 15 | 3423 | 137 | 25 | None |
| | 3-c | 62 | 18 | 3109 | 90 | 35 | None |
| | 3-d | 60 | 16 | 3057 | 71 | 43 | None |
| | 3-e | 61 | 14 | 3115 | 54 | 58 | None |
| Example 4 | 4-a | 70 | 21 | 2977 | 129 | 23 | None |
| | 4-b | 54 | 15 | 3287 | 110 | 30 | None |
| | 4-c | 48 | 13 | 3198 | 75 | 42 | None |
| | 4-d | 50 | 10 | 3246 | 80 | 41 | None |
| | 4-e | 46 | 9 | 3100 | 59 | 53 | None |
| Example 5 | 5-a | 51 | 26 | 3100 | 98 | 32 | None |
| | 5-b | 66 | 22 | 3011 | 104 | 29 | None |
| | 5-c | 45 | 10 | 2967 | 81 | 37 | None |
| | 5-d | 53 | 16 | 3153 | 70 | 45 | None |
| | 5-e | 40 | 16 | 2907 | 66 | 44 | None |

TABLE 11

| | | | | | Polishing | | |
|---|---|---|---|---|---|---|---|
| | | | | Polishing | speed of | | |
| | | | | speed of | silicon | | |
| | | Dishing | Erosion | tungsten | ox-ide | | |
| | Conditions | (Å) | (Å) | (Å/min) | (Å/min) | Selectivity | Scratch |
| Comparative | 6-a | 80 | 18 | 2789 | 146 | 19 | None |
| Example 1 | 6-b | 78 | 22 | 2681 | 167 | 16 | None |
| | 6-c | 68 | 19 | 2776 | 143 | 19 | None |
| | 6-d | 94 | 24 | 2985 | 130 | 23 | None |
| | 6-e | 56 | 20 | 2468 | 166 | 15 | None |
| Comparative | 7-a | 123 | 45 | 2891 | 317 | 9 | Exist |
| Example 2 | 7-b | 137 | 37 | 2745 | 209 | 13 | Exist |
| | 7-c | 112 | 32 | 3014 | 110 | 27 | Exist |
| | 7-d | 110 | 36 | 2946 | 84 | 35 | Exist |
| | 7-e | 107 | 49 | 2568 | 46 | 56 | Exist |
| Comparative | 8-a | 91 | 38 | 2971 | 201 | 15 | Exist |
| Example 3 | 8-b | 89 | 34 | 2896 | 177 | 16 | Exist |
| | 8-c | 76 | 29 | 2701 | 129 | 21 | Exist |
| | 8-d | 80 | 28 | 2664 | 66 | 40 | Exist |
| | 8-e | 72 | 30 | 2698 | 70 | 39 | Exist |
| Comparative | 9-a | 80 | 44 | 2843 | 168 | 17 | None |
| Example 4 | 9-b | 88 | 40 | 2546 | 113 | 22 | None |
| | 9-c | 75 | 38 | 2672 | 188 | 14 | None |
| | 9-d | 90 | 39 | 2410 | 179 | 13 | None |
| | 9-e | 77 | 48 | 2561 | 146 | 18 | None |

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

1.-10. (canceled)

11. A polishing composition, comprising:
metal oxide particles as abrasive grains, wherein the full width at half maximum of a peak portion having the maximum diffracted intensity in an X-ray powder diffraction pattern of the metal oxide particles is less than 1°; and
two or more varieties of water-soluble polymers having different weight-average molecular weights as a selectivity control agent, wherein the water-soluble polymers differ in weight-average molecular weight by 10 times or more.

12. The polishing composition according to claim 11, wherein the metal oxide particles contain any one variety selected from the group consisting of titanium oxide, zirconium oxide, cerium oxide, aluminum oxide, manganese oxide, mixtures of two or more of these metal oxides, and complex oxides containing at least one of these metal oxides.

13. The polishing composition according to claim 11, wherein the water-soluble polymers comprise at least one variety selected from the group consisting of policarboxylic acid and salts thereof, poly(styrenesulfonic acid) and salts thereof, polyacrylic acid and salts thereof, polyvinylpyrrolidone, anion modified polyvinyl alcohol, polyacrylamide, and polyether.

14. The polishing composition according to claim 12, wherein the water-soluble polymers comprise at least one variety selected from the group consisting of policarboxylic acid and salts thereof, poly(styrenesulfonic acid) and salts thereof, polyacrylic acid and salts thereof, polyvinylpyrrolidone, anion modified polyvinyl alcohol, polyacrylamide, and polyether.

15. The polishing composition according to claim 11, further comprising an oxidizing agent.

16. The polishing composition according to claim 12, further comprising an oxidizing agent.

17. The polishing composition according to claim 13, further comprising an oxidizing agent.

18. The polishing composition according to claim 14, further comprising an oxidizing agent.

19. The polishing composition according to claim 15, wherein the oxidizing agent comprises at least one variety selected from the group consisting of peroxides and iron(III) salts.

20. The polishing composition according to claim 18, wherein the oxidizing agent comprises at least one variety selected from the group consisting of peroxides and iron(III) salts.

21. The polishing composition according to claim 19, wherein the peroxide comprises at least one variety selected from the group consisting of persulfuric acid, periodic acid, perchloric acid, salts thereof, and hydrogen peroxide.

22. The polishing composition according to claim 20, wherein the peroxide comprises at least one variety selected from the group consisting of persulfuric acid, periodic acid, perchloric acid, salts thereof, and hydrogen peroxide.

23. The polishing composition according to claim 19, wherein the iron(III) salt comprises at least one variety selected from the group consisting of iron(III) sulfate, iron(III) nitrate, iron(III) chloride, iron(III) oxalate, potassium tris(oxalate)ferrate(III), ammonium hexacyanoferrate(III), potassium hexacyanoferrate(III), iron(III) citrate, and ammonium iron(III) citrate.

24. The polishing composition according to claim 20, wherein the iron(III) salt comprises at least one variety selected from the group consisting of iron(III) sulfate, iron(III) nitrate, iron(III) chloride, iron(III) oxalate, potassium tris(oxalate)ferrate(III), ammonium hexacyanoferrate(III), potassium hexacyanoferrate(III), iron(III) citrate, and ammonium iron(III) citrate.

25. The polishing composition according to claim 21, wherein the iron(III) salt comprises at least one variety selected from the group consisting of iron(III) sulfate, iron(III) nitrate, iron(III) chloride, iron(III) oxalate, potassium tris(oxalate)ferrate(III), ammonium hexacyanoferrate(III), potassium hexacyanoferrate(III), iron(III) citrate, and ammonium iron(III) citrate.

26. The polishing composition according to claim 22, wherein the iron(III) salt comprises at least one variety selected from the group consisting of iron(III) sulfate, iron(III) nitrate, iron(III) chloride, iron(III) oxalate, potassium tris(oxalate)ferrate(III), ammonium hexacyanoferrate(III), potassium hexacyanoferrate(III), iron(III) citrate, and ammonium iron(III) citrate.

27. A polishing method comprising polishing of a semiconductor substrate by using the polishing composition according to claim 11.

28. A polishing method comprising polishing of a semiconductor substrate by using the polishing composition according to claim 26.

29. The polishing method according to claim 27, wherein the semiconductor substrate contains a metal layer.

30. The polishing method according to claim 29, wherein the metal layer comprises tungsten or tungsten alloy.
